(19) United States
(12) Patent Application Publication
(10) Pub. No.: US 2011/0253207 A1
(43) Pub. Date: Oct. 20, 2011

(54) SOLAR CELL DEVICE AND METHOD FOR MANUFACTURING SAME

(75) Inventor: Michal Martinek, Buchs (CH)

(73) Assignee: OERLIKON SOLAR AG, TRUEBBACH, Truebbach (CH)

(21) Appl. No.: 13/126,785

(22) PCT Filed: Nov. 4, 2009
(86) PCT No.: PCT/EP2009/064581

§ 371 Date: Jul. 8, 2011

Related U.S. Application Data
(60) Provisional application No. 61/111,443, filed on Nov. 5, 2008.

(51) Int. Cl. H01L 31/06; H01L 31/0224; H01L 31/18

(52) U.S. Cl. 136/255; 438/57; 136/256; 257/E31.126

(57) ABSTRACT

It is an object of the present invention to enlarge flexibility with, respect to material selection for transparent conductive oxide layers within a solar cell device especially in view of the respective, material-specific vacuum deposition processes. This object is resolved by a solar cell device which comprises at least one thin film solar cell and an electrically conductive, transparent oxide layer wherein the addressed electrically conductive, transparent oxide layer is of doped TiOx.

The present invention relates to solar cell devices which comprise at least one thin film solar cell as well as to a method for manufacturing such a solar device.

Solar cell devices of the type as addressed here are devices which convert light, especially sun light, by photovoltaic effect into direct current (DC) electrical power. For low-cost mass production, such devices are of high interest since they allow using glass, glass ceramics or other rigid substrates as carrier substrate. The at least one thin film solar cell of the solar cell device consists of a sequence of thin layers. Thereby and depending on the material selected to realize the respective layers of the solar cell as well as additional layers, especially vacuum deposition processes are used. Different vacuum processes may be selected, which all are in fact known from the semiconductor manufacturing technology as e.g. PVD, CVD, PECVD, APCVD, etc.

A thin film solar cell in minimal configuration comprises a first electrode layer, a p-i-n or n-i-p layer stack and a second electrode. Thus, each solar cell includes an i-type layer sandwiched between a positively doped, p-type layer and a negatively doped, n-type layer. The i-type layer consists of an intrinsic semiconductor, whereby “intrinsic” addresses such semiconductor material being undoped or being neutrally doped. This i-type layer occupies the predominant part of the thickness of the thin film p-i-n layer stack. Photoelectric conversion occurs primarily in the i-type layer. A thicker i-type layer is preferred from the standpoint of light absorption, though an unnecessarily thick layer leads to an increase of manufacturing costs e.g. by a decrease of throughput and deteriorate overall efficiency.

The p-type and n-type layers, often called “window layers”, serve to generate an electric diffusion potential across the i-type layer. The magnitude of this diffusion potential influences the value of the open circuit voltage V_{oc} that is one of the critical characteristics of a thin film solar cell. These conductive windows layers do not contribute to the photovoltaic conversion. It is preferred that the addressed p-type and n-type layers are realized as thin as possible within a range ensuring generation of sufficient diffusion potential and sufficient electrical conductivity. Further, at least that of the addressed p- or n-type layers which is exposed to incident light has to be of high transparency.

Depending on the crystallinity of the i-type layer, solar cells are named amorphous -a- or microcrystalline -μc-solar cells. As commonly the semiconductor material used for the i-type layer is silicon, a-Si and μc-Si solar cells are widely known. We understand throughout the present description and claims under “microcrystalline” a material which comprises at least 50 vol % of micro- or nano-crystals embedded in an amorphous matrix.

So as to tap off electric power from a solar cell device n-i-p or p-i-n layer structure of the at least one solar cell is sandwiched between two electrode layers. One thereof must on one hand be conductive to fulfill the object of an electrode and must additionally be transparent for the impinging light. This layer is customarily realized of a transparent conductive oxide TCO.

Another well-known application of a transparent conductive oxide is in context with solar devices which comprise at least two solar cells which are optically and electrically in series. They are called optically in series because a part of the light which impinges on the first solar cell is transmitted also through the second solar cell. The solar cells are called electrically in series because the photovoltaically generated voltages of the two solar cells appear in series and are thus added. Constructionally the two or more thin film solar cells of such a solar cell device appear stacked one upon the other. This device structure is predominantly realized to exploit the largest possible spectrum of impinging light. Thereby and considered in direction of impinging light a first solar cell—called top cell—is generically sensitive in a first wavelength spectrum, whereas a subsequent second solar cell—called bottom cell—is generically sensitive in a different wavelength spectrum. Thereby, the spectrum in which a solar cell is predominantly effective is predominantly controlled by the material and the crystallinity of the i-type layer. Known is e.g. the combination of an a-Si solar cell having a photovoltaic efficiency in a shorter wavelength spectrum with a μc-Si solar cell which has a photovoltaic efficiency in a longer wavelength spectrum of the impinging solar light spectrum. However and depending on the specific target, combinations of a-Si/a-Si or μc-Si/μc-Si are possible additionally to combinations, whereat not only crystallinity of the silicon semiconductor material of the i-type layer is varied but additionally the selected semiconductor material.

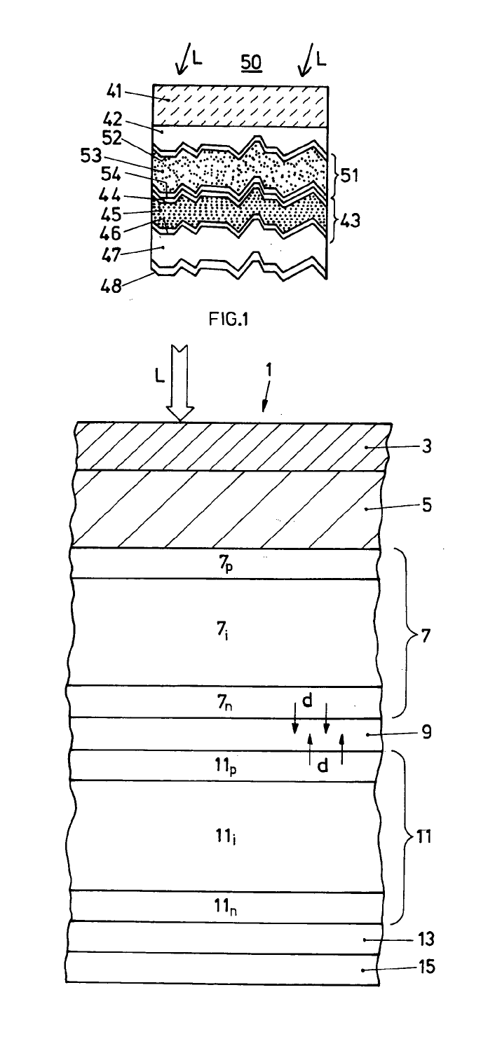

FIG. 1 shows schematically a known solar cell device which comprises two thin film solar cells, often called “tandem” solar cell structure. The device is generically addressed by reference No. 50. It comprises a carrier substrate 41, a layer of transparent conductive oxide TCO 42 as front electrode, a first solar cell 51, the top cell, which is formed e.g. by layers of hydrogenated silicon, namely by a window layer 52, an intrinsic type layer 53 and second window layer 54. The second subsequent solar cell 43, the bottom cell, is formed by three sublayers e.g. of hydrogenated silicon, namely by two window layers 44 and 46 and the intrinsic-type layer 45. A rear contact layer 47, the second electrode layer and a reflective layer 48 complement the basic structure of such a known example of a solar cell device. In FIG. 1 the arrows L indicate the impinging light.

In the example of FIG. 1 the intrinsic-type layer 53 of the top cell 51 is e.g. of amorphous hydrogenated silicon, whereas the intrinsic-type layer 45 of bottom cell 43 is of microcrystalline hydrogenated silicon.

The a-Si top cell 51 has a significant photovoltaic conversion efficiency in a spectral range up to wavelengths of about 800 nm whereas the μc-Si bottom cell has a significant photovoltaic conversion efficiency up to about 1100 to 1200 nm.

Solar devices with two or more than two stacked solar cells as exemplified in FIG. 1 are generically used to increase the efficiency of the overall device in terms of output power. The optimum performance is thereby reached when the generated currents of both cells or of all cells are matched, i.e. are equal. Thereby, it is evident that due to the electrically serial connection of the cells the overall resulting current is governed by the smallest current generated in one of the addressed cells. As an example in the case of silicon based tandem cells as exemplified in FIG. 1 and with typical thicknesses of the i-layers of the a-Si cell of 200 nm and of the μc-Si cell of 1500 nm respective current densities of 12 mA/cm² and of 24 mA/cm² are generated by the a-Si top cell and the μc-Si bottom cell respectively. In such a case it is desirable to increase the current density of the top cell which may not—or only to a limited extent—be achieved by just increasing the thickness of the i-layer of the top cell. This because of the trade-off that thereby the internal electric field and the charge mobility is decreased. There thus exist narrow limits for increasing the addressed current density of a cell just by increasing the thickness of its i-layer.

To cope with this problem it is known to provide an intermediate reflector between subsequent solar cells which are stacked one upon the other, e.g. and with an eye on FIG. 1, between the top cell 51 and the bottom cell 43. By such intermediate reflector a part of the impinging light after having transited through the top cell is reflected back into the top cell. Thereby, the current density of the top cell is increased and thus the overall current of the device and its efficiency.

Such an intermediate reflector is known from the U.S. Pat. No. 5,021,100. Thereby, there is provided an electrically conductive or a dielectric film between subsequent solar cells, which acts as a semi-transparent reflector.

Thereby, as material for the intermediate reflector layer there is mentioned ITO, ZnO, TiO and SiO₂ with respective thicknesses. If as a material for the intermediate reflector layer a non-electrically conductive material is selected as is obviously the case for SiO₂, the addressed intermediate reflector layer is provided with distributed apertures so as to allow electric current to bypass the intermediate reflector layer. Further attention is drawn to the EP 1 478 030 and to the EP 1 650 811 with respect to provision of an intermediate reflector and respective materials to be used therefore.

As was already addressed above the deposition of layers of different materials requires often selection of respectively suited vacuum deposition processes. Therefore, one important criterion for selecting the respective materials is not only their optical and electrical characteristics, but additionally the vacuum process type which is to be used for depositing a layer of the respective material and in context with vacuum process types used to deposit other layers of the device.

Often the layers of the solar cell, especially of silicon based solar cells, are best deposited by plasma-enhanced chemical vapor deposition, whereas materials which have been proposed to be used as a transparent conductive oxide are often not suited to be deposited by the addressed PECVD process.

Moreover, materials which have been proposed for transparent conductive oxide layers are not resistant to plasma activated hydrogen as often used for depositing a subsequent layer of the device.

With an eye on large-scale industrial solar cell device manufacturing it is one of the considerations to be made when optimizing such manufacturing to deposit subsequent layers of the solar cell device by the same type of vacuum deposition process so as to minimize the number of changing from one vacuum process type to another one.

It is thus an object of the present invention to enlarge flexibility with respect to material selection for transparent conductive oxide layers within a solar cell device especially in view of the respective, material-specific vacuum deposition processes.

This object is resolved by a solar cell device which comprises at least one thin film solar cell and an electrically conductive, transparent oxide layer wherein the addressed electrically conductive, transparent oxide layer is of doped TiOₓ, wherein 1.6≦x≦2, in particular wherein x is essentially 2. In the addressed case of x being essentially 2, the before-addressed layer is of doped titanium dioxide (TiO₂). With x<2, the before-addressed layer is of doped sub-stoichiometric titanium dioxide.

On one hand doped TiOₓ is perfectly suited to be deposited by plasma enhanced chemical vapor deposition and on the other hand is highly resistive to activated hydrogen. It is made electrically conductive by doping which makes possible to continuously deposit such doped TiOₓ also as an intermediate reflector layer continuously without necessitating the provision of apertures to allow electric current to bypass the layer.

In one good embodiment of the solar cell device according to the invention which may be combined with any subsequently addressed embodiment unless in contradiction, the layer of doped TiOₓ is at least a part of an electrode layer to tap off electric energy from the solar cell device. Thus, the addressed layer is perfectly suited to be applied with an eye on FIG. 1 as the TCO top electrode.

In a further good embodiment of the solar cell device according to the present invention which may be combined with any of the precedingly addressed and subsequently addressed embodiments unless in contradiction, the device comprises at least a first thin film solar cell for receiving incident light and a second thin film solar cell receiving light transmitted through the addressed first thin film solar cell and wherein the addressed layer of doped TiOₓ is at least a part of a layer structure, thereby especially acting as an intermediate reflector layer structure which is arranged between the first and the second thin film solar cells.

In context with such arrangement of the doped TiOₓ it should be considered that the doping of the per se non-electrically conductive TiOₓ may be established in some cases by the same dopant as is provided at one of the adjacent window layers of adjacent solar cells. Further, it should be considered that the addressed doping of the TiOₓ layer may be established by the same doping material as applied to both of the adjacent window layers, i.e. by a p- as well as by a n-dopant in view of the fact that, generically, electroconductivity is to be realized at the per se dielectric TiOₓ layer. Further and in this context it should also be considered that the addressed doping of the TiOₓ layer needs not necessarily be applied specifically for the addressed layer, but may be established completely or to a part by diffusion of the respective p- and/or n-dopants from adjacent windows layers into the TiOₓ material. The extent to which this effect of diffusion may be exploited depends on the thickness with which the addressed layer is to be provided.

Accordingly one good embodiment of the solar cell device according to the present invention which may be combined with any of the preaddressed and of the subsequently addressed embodiments, the layer of doped TiOₓ comprises the same dopant which is present in an adjacent layer.

In a further embodiment of the device according to the present invention which may be combined with any of the precedingly addressed embodiments as well as with any of the subsequently addressed embodiments, the material of a layer adjacent to the layer of electrically conductive, transparent oxide, which is of doped TiOₓ, comprises hydrogen.

In a further embodiment of the device according to the present invention which may be combined with any of the precedingly addressed embodiments as well as with any of the subsequently addressed embodiments unless in contradiction, the addressed doped TiOₓ is at least one of TiOₓ:H, N-TiOₓ, C-TiOₓ, Ag-TiOₓ, Y-TiOₓ, Nb-TiOₓ, Ta-TiOₓ, and in the case of x=2 (TiOₓ =TiO₂): TiO₂:H, N-TiO₂, C-TiO₂, Ag-TiO₂, Y-TiO₂, Nb-TiO₂, Ta-TiO₂.

In a further good embodiment which may be combined with any of the precedingly addressed embodiments as well as with any of the subsequently addressed embodiments unless in contradiction, the doped TiOₓ is doped with a non-metal dopant. In a further good embodiment which may be combined with any of the precedingly addressed as well as with any of the subsequently addressed embodiments unless in contradiction, the doped TiOₓ comprises a metal dopant.

The method for manufacturing a solar cell device according to the present invention, which comprises at least one solar cell and at least one layer of an electrically conductive, transparent oxide, comprises depositing of the electrically conductive, transparent oxide layer of doped TiOₓ by plasma enhanced chemical vapor deposition of at least the TiOₓ, wherein 1.6≦x≦2, in particular wherein x is essentially 2. In the addressed case of x being essentially 2, the before-addressed layer is of doped titanium dioxide (TiO₂). With x<2, the before-addressed layer is of doped sub-stoichiometric titanium dioxide.

Thereby, it is addressed that if the dopant is provided into the TiOₓ layer exclusively by diffusion, there is no need to apply such dopant during the plasma enhanced chemical vapor deposition of the addressed oxide layer.

Clearly and if a dopant is additionally to be applied or the addressed conductive transparent oxide layer is not adjacent to a doped layer, the dopant for the TiOₓ layer is applied during the addressed plasma enhanced chemical vapor deposition.

The invention shall now further be explained by an example which is shown in FIG. 2.

FIG. 2 schematically shows a solar cell device with two stacked thin film solar cells and wherein the present invention is realized by providing the electrically conductive, transparent oxide layer as an intermediate reflector layer. The solar cell device 1, part thereof being schematically shown in FIG. 2, comprises a substrate 3 e.g. of a glass and subsequently the electrode layer 5 of a transparent, conductive oxide TCO also called front contact layer. The incident light is addressed in FIG. 2 by the arrow L. Subsequent to the electrode layer 5 there is provided the top solar cell 7 with p-doped window layer 7ₚ, intrinsic-type layer 7ᵢ and n-doped window layer 7ₙ. Subsequent to the window layer 7ₙ there is provided an intermediate layer structure 9 which at least comprises a layer of doped TiOₓ with 1.6≦x≦2, more particularly a layer of doped TiO₂. The layer structure 9 may thereby act as an intermediate reflector layer structure. Subsequent to the intermediate layer structure 9 there follows the bottom solar cell 11 comprising the p-doped window layer 11ₚ, the intrinsic layer 11ᵢ and the second n-doped window layer 11ₙ. Subsequently there is provided the second electrode layer 13, also called back contact layer 13, as well as a back reflector layer 15. As commonly known the function of back contact and of back reflector may be realized by one layer.

The intermediate layer structure 9 comprises at least one layer of doped TiOₓ or consists of such layer of doped TiOₓ (1.6≦x≦2). As schematically shown by the arrows d doping of the TiOₓ dielectric material may comprise or even may consist of the n-dopant of layer 7ₙ and/or of the p-dopant of layer 11ₚ which may be established by selecting the respective dopant when depositing, thereby most preferably PECVD depositing, the addressed one layer of layer structure 9. Alternatively, the addressed doping by the dopants of at least one of the adjacent window layers 7ₙ and 11ₚ may be established or co-established by diffusion of the respective dopants into the TiOₓ layer.

Further, the one layer of layer structure 9 may be of hydrogenated doped stoichiometric or sub-stoichiometric titanium dioxide TiOₓ:H (1.6≦x≦2) or, generically, of a non-metal doped (stoichiometric or sub-stoichiometric) titanium dioxide, thereby especially of at least one of C-TiOₓ and of N-TiOₓ or, additionally or alternatively, of metal doped titanium dioxide (stoichiometric or sub-stoichiometric) as of at least one of Ag-TiOₓ, Y-TiOₓ, Nb-TiOₓ, Ta-TiOₓ (1.6≦x≦2). Thereby, it must be emphasized that typically such titanium dioxide based coatings are highly resistant to an atmosphere of plasma activated hydrogen and are thus highly suited to be deposited according to FIG. 2 prior to depositing in such atmosphere a subsequent layer.

The addressed one layer in layer structure 9 is PECVD-deposited.

Thereby, the following process parameters are recommended, in particular in case of x=2:
Total pressure: between 0.1 and 3 mbar
Power density: up to 1 W/cm² substrate surface
Precursor gases: Metal-organic compounds of titanium, e.g. TiCl₄, titanium tetraisopropoxide; flow rate between 20 and 2000 sccm
Reactive gases: O₂ and, for doping purposes, e.g. CH₄, N₂, H₂, NbCl₅ with a flow rate between 20 and 2000 sccm
Deposition temperature: between 20° C. and 230° C.
Thickness of the layer of doped TiO₂: ranging from 5-150 nm

The index of refraction is between 1.6 and 2.4.

1. A solar cell device comprising at least one thin film solar cell and an electrically conductive, transparent oxide layer, said electrically conductive, transparent oxide layer being of doped TiOₓ, wherein 1.6≦x≦2.

2. The solar cell device of claim 1, wherein said layer is at least a part of an electrode layer to tap off electrical energy from the solar cell device.

3. The solar cell device of one of claim 1 or 2, wherein said device comprises at least a first thin film solar cell for receiving incident light and a second thin film solar cell receiving light transmitted through said first thin film solar cell, said layer being at least a part of a layer structure between said first and second thin film solar cells.

4. The solar device according to one of claims 1 to 3, wherein said layer of doped TiOₓ comprises the same dopant which is present in an adjacent layer.

5. The solar cell device of one of claims 1 to 4, wherein the material of a layer adjacent said layer of doped TiOₓ comprises hydrogen.

6. The device of one of claims 1 to 5, wherein said doped TiOₓ is at least one of TiOₓ:H, N-TiOₓ, C-TiOₓ, Ag-TiOₓ, Y-TiOₓ, Nb-TiOₓ, Ta-TiOₓ.

7. The solar device of one of claims 1 to 6, wherein said doped TiOₓ is non-metal doped.

8. The device of one of claims 1 to 7, wherein said doped TiOₓ is metal doped.

9. The device of one of claims 1 to 9, wherein x is essentially 2.

10. A method for manufacturing a solar cell device comprising at least one solar cell and at least one layer of an electrically conductive, transparent oxide comprising depositing said layer of doped TiOₓ by plasma enhanced chemical vapor deposition of at least TiOₓ, wherein 1.6≦x≦2.

11. The method of claim 10, further comprising depositing a further layer upon said layer of doped TiOₓ from an atmosphere comprising plasma activated hydrogen.

12. The method of claim 10 or claim 11, wherein x is essentially 2.
